(19) United States
(12) Patent Application Publication
(10) Pub. No.: US 2006/0279380 A1
(43) Pub. Date: Dec. 14, 2006

(54) Second order bandpass filter

(75) Inventors: Shyh-Jong Chung, Hsinchu (TW); Chun-Fu Chang, Hsinchu (TW)

Correspondence Address: APEX JURIS, PLLC;TRACY M HEIMS, LAKE CITY CENTER, SUITE 410, 12360 LAKE CITY WAY NORTHEAST, SEATTLE, WA, 98125, US

(73) Assignee: Nation Chiao Tung University, Hsinchu (TW)

(21) Appl. No.: 11/150,309

(22) Filed: Jun. 10, 2005

(51) Int. Cl. H03H 7/01

(52) U.S. Cl. 333/170; 333/177

(57) ABSTRACT

A second-order bandpass filter having an improved frequency response is disclosed, in which a grounding capacitor is connected electrically to a two-port network as a feedback path so as to provide two finite transmission zeros. With the two transmission zeros, signals of second harmonic frequency and GSM signals may be blocked out from the pass band of the filter and thus filtered out. As such, the filter may be utilized in wireless local area network (WLAN) application. Further, since no extremely small value component is used within the filter, the frequency response may not be influenced by a manufacturing process of the filter. In addition, the thus formed filter has a relatively smaller volume.

### BACKGROUND OF THE INVENTION

1. Field of the Invention

The present invention relates to a bandpass filter. More particularly, the present invention relates to a second-order bandpass filter having an improved frequency response.

2. Descriptions of the Related Art

Filter is a passive device generally used in communications, electronic and electrical fields, particularly in wireless communications field for filtering out noises so that a transmitted signal through the filter may be used by a receiver. Bandpass filter is a filter which allows only a signal whose frequency is within a specific frequency band (referred to as a pass band) to pass there through and other signals having other frequencies (referred to as a stop band), i.e. noises, are otherwise filtered out. Therefore, the bandpass filter can be indispensable to the wireless communications field. Since the band pass filter is used for noise filtering, it is expected to have a good frequency response. Good frequency response makes a signal transmitted through the filter clear enough to be received and identified by the receiver. However, poor frequency response may cause a poor signal reception at the receiver and even makes the signal received stultified.

Second-order bandpass filter is the most used filter. A capacitor and an inductor in series connected to another capacitor and another inductor in parallel and grounded may form a simplest second-order bandpass filter (the capacitor and inductor in series or parallel alone forms a first-order bandpass filter). Such second-order bandpass filter has at least a transmission zero (abbreviated as zero in this specification) corresponding to a cut-off frequency. A signal whose frequency is within two cut-off frequencies is intended to be transmitted or received while a signal with frequency outside the frequency band formed by the two cut-off frequencies is to be filtered out. Such zero includes infinite zero and finite zero, the infinite zero corresponding to an infinite frequency while the finite zero corresponding to a finite frequency. Noises may not be actually filtered out with respect to the infinite zero but may only be filtered out with the provision of the finite zero.

A second-order bandpass filter having two finite zeros is described in an article by Lap Kun Yeung and W. R. Wu, entitled “A compact Second-Order LTCC Bandpass Filter with Two Finite Transmission Zeros,” in IEEE Trans. Microwave Theory Tech., vol. 51, pp. 337-341, February 2003 (hereinbelow as first reference). In this second-order bandpass filter, a coupling capacitor C provides a feedback path and thus generates the two finite zeros, shown in FIG. 1. Although two finite zeros are provided, they are not both corresponding to interference signals (with frequencies of 1.8 GHz, 1.9 GHz and 4.8 GHz in IEEE802.11b/g specification used in wireless LAN application) or exclude these interference signals outside the pass band and thus may not provide a good suppression over these interference signals, wherein the interference signals are generated by components such as an oscillator/mixer in a transmitter and GSM signals. Further, second harmonic frequency signal of the operating signal can also not be efficiently filtered out (since its frequency 4.8-5 GHz may not correspond to −30 dB suppression). Further, the used coupling capacitor C is only 0.1 μF and frequency response of the filter is thus susceptible to vary due to inaccuracy of fabrication process. In case that the coupling capacitor C has a variation when the filter is fabricated, the frequency response may also vary. In view of this characteristic, such second-order bandpass filter is not ideal.

Another second-order bandpass filter is set forth by Sutono, J. Laskar and W. R. Smith, entitled “Development of Integrated Three Dimensional Bluetooth Image Reject Filter,” in IEEE Microwave Symposium Digest., 2000 IEEE MIT-S International, vol. 1, pp. 339-342, June 2000 (hereinbelow second reference). In the second-order bandpass filter, only a zero is provided and thus signals in some frequency band may not be filtered out. As a result, the aforementioned second harmonic frequency signal may not be suppressed enough and further a central band of the filter has a too large insertion loss, making the transmitted signal having an insufficient level of power. Thus, the received signal through such filter may not achieve a satisfied quality, making the filter disqualified to be used in the wireless LAN application.

In view of the above, it is generally sought with respect to a second-order bandpass filter having an improved frequency response in the same field.

### SUMMARY OF THE INVENTION

It is, therefore, an object of the present invention to provide a second-order bandpass filter having an improved frequency response in which two finite zeros, a low-loss pass band are provided and through which a second harmonic frequency signal of a operating signal and GSM signals may be filtered out.

To achieve the above object, the second-order bandpass filter according to the present invention comprises a two-port network and a grounding capacitor. The two-port network comprises a first port and a second port. The first port comprises a first blocking capacitor coupled electrically to an input signal at one end to filter out a direct current (DC) component of the input signal, a first resonance capacitor coupled electrically to the other of the first blocking capacitor at one end and a first resonance inductor coupled electrically to the other of the first blocking capacitor at one end. The second port comprises a second blocking capacitor coupled electrically to an output signal at one end to filter out a DC component of a signal at the second port, a second resonance capacitor coupled electrically to the other of the second blocking capacitor at one end and a second resonance inductor coupled electrically to the other of the second blocking capacitor at one end and coupled electrically to ground at the other end, wherein mutual inductance is presented between the first and second resonance inductors.

With a proper design, the second-order bandpass filter may provide two finite zeros corresponding to frequencies of between 1.8 to 1.9 GHz and between 3.6 to 4.8 GHz, a pass band having a central frequency of 2.45 GHz and a frequency bandwidth greater than 100 MHz. With such frequency response, the second harmonic frequency signal and GSM signals may be filtered out. Further, the filter features a low insertion loss with respect to the pass band, leading the filter to be well used in the wireless LAN application. In addition, frequency difference of the two zeros may be adjusted by directly varying capacitance of the grounding capacitor and thus used directly in other applications.

The present invention may at least achieve the following advantages. 1. Two finite zeros are provided and thus noises may be efficiently filtered out. 2. Frequency difference with respect to the two finite zeros may be adjusted by directly changing the grounding capacitance. 3. No component having an extremely low value is used and thus frequency response may be fixed among such filters. 4. Small volume making easy to be integrated with other components.

### BRIEF DESCRIPTION OF THE DRAWINGS

The accompanying drawings, which are incorporated into and constitute a part of this specification, illustrate one or more embodiments of the present invention and, together with the detailed description, serve to explain the principles and implementations of the invention. The figures are not to scale. In the drawings:

FIG. 1 shows a schematic view of a conventional second-order bandpass filter;

FIG. 2 shows a schematic structure diagram of a second-order bandpass filter according to the present invention;

FIG. 3 is an equivalent circuit diagram of the second-order bandpass filter according to the present invention;

FIG. 4 shows a set of frequency response curves of the second-order bandpass filter according to the present invention; and

FIG. 5 shows another set of frequency curves of the second-order bandpass filter according to the present invention.

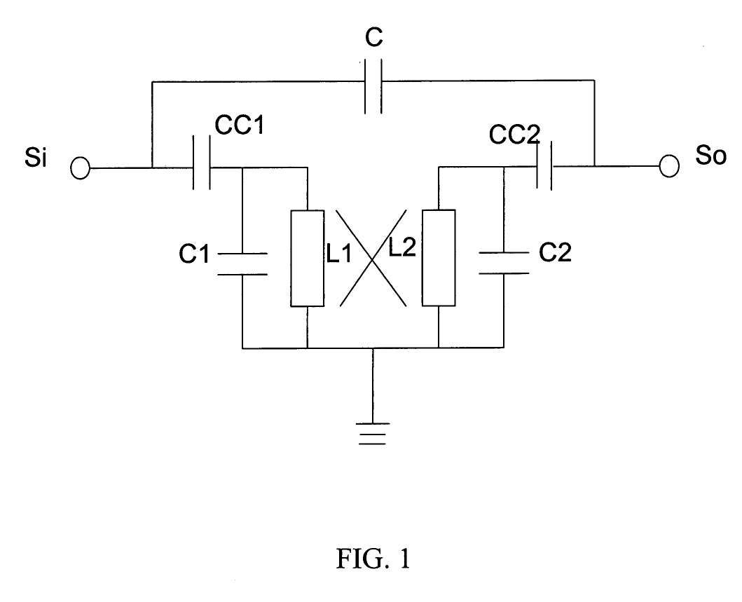

### DETAILED DESCRIPTION OF THE INVENTION

The present invention discloses a second-order bandpass filter, which will be described taken from the preferred embodiments with reference to the annexed drawings.

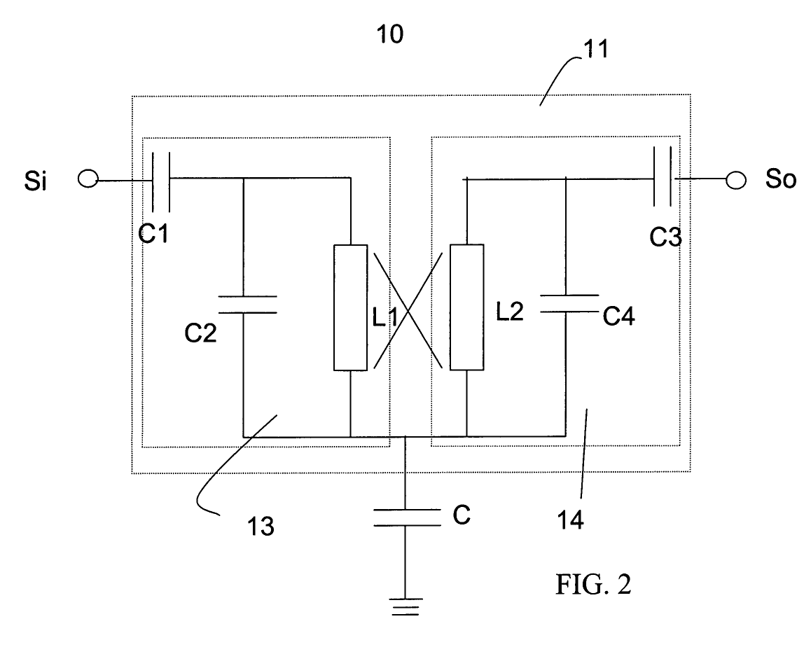

FIG. 2 shows a schematic structure diagram of a second-order bandpass filter according to the present invention. As shown, the second-order bandpass filter 10 comprises a two-port network 11 and a grounding capacitor C. The two-port network 11 comprises a first port 13 and a second port 14. An input signal Si is inputted at the first port 13 and an output signal So is outputted at the second port 14.

The first port 13 comprises a first blocking capacitor C1, a first resonance capacitor C2 and a first resonance inductor L1. The input signal Si is first inputted to the first blocking capacitor C1 at one end and a DC component thereof is filtered out. The first resonance capacitor C2 is coupled electrically to the other of the first blocking capacitor C1 at one end. The first resonance inductor L1 is coupled electrically to the other of the first blocking capacitor C1 at one end.

The second port 14 comprises a second blocking capacitor C3, a second resonance capacitor C4 and a first resonance inductor L2. An output signal So is outputted from the second blocking capacitor C3 at one end and a DC component thereof is filtered out. The second resonance capacitor C4 is coupled electrically to the other of the second blocking capacitor C3 at one end. The second resonance inductor L2 is coupled electrically to the other of the second blocking capacitor C3 at one end. The grounding capacitor C is coupled electrically to the first resonance capacitor C3, the first resonance inductor L1, the second resonance capacitor C4 and the second inductor L2 at one end and coupled electrically to ground at the other.

The grounding capacitor C forms a feedback path from the second port 14 to the first port 13 and provides two finite zeros for the filter 10. In addition, a mutual induction is generated between the first inductor L1 and the second inductor L2, which is represented by “X” in the drawing.

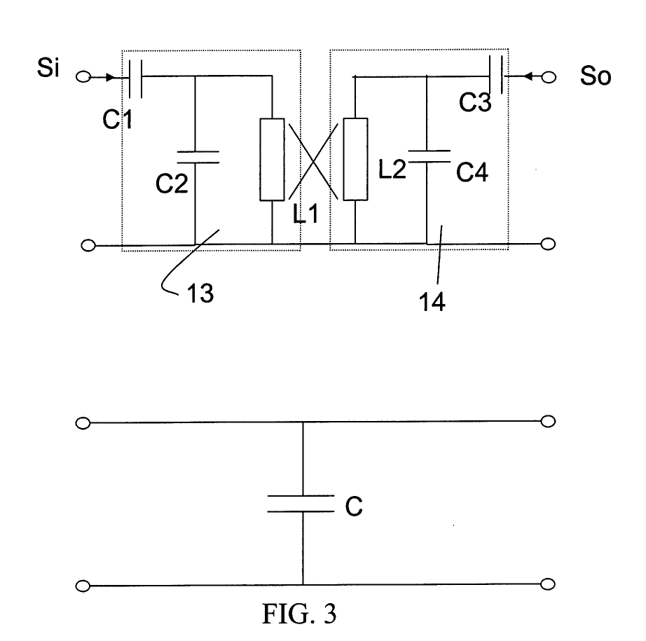

FIG. 3 shows an equivalent diagram of the bandpass filter according to the present invention, and the feedback path formed by the capacitor C from the second port 14 to the first port 13 may be seen therein.

To make frequency response of the second-order bandpass filter comply with wireless LAN application specification, frequency of noises have to fall outside the pass band formed by the two finite zeros. To this end, capacitances and inductances used in the filter have to be properly given so that central frequency, frequency bandwidth and zeros may be specified in compliance with the requirements in the application. Now, assuming the input signal Vi has a progressive wave Vi+ and a bouncing wave Vi− and the output signal Vo has a progressive wave Vo+ and a bouncing wave Vo−, which may be presented by the equation below:

$$[ \begin{matrix}Vo + \\ Vo -\end{matrix} ] = [ \begin{matrix}{S}_{11} & {S}_{12} \\ {S}_{21} & {S}_{22}\end{matrix} ] [ \begin{matrix}Vi + \\ Vi -\end{matrix} ] , \qquad ( Eq . 1 )$$

wherein Sᵢⱼ is a scattering parameter being a function of frequency ω and S₂₁ is the generally termed frequency response. This representative relationship is apparent to those skilled in the art, and will be omitted in this specification.

A transfer function is defined as a gain of the filter and a function of frequency ω. To obtain the two finite zeros, the transfer function for the filter should be determined first and then let the numerator of the transfer function to be zero. At this time, the following equation may be obtained:

$${ω}^{4} \frac{{C}_{2} {C}_{4}}{M} ( {L}_{1} {L}_{2} - {M}^{2} ) - {ω}^{2} ( C + \frac{{L}_{1} {C}_{2}}{M} + \frac{{L}_{2} {C}_{4}}{M} ) + \frac{1}{M} = 0. \qquad ( Eq . 2 )$$

By solving Eq. 2, two zero frequencies may be obtained (with the other two solved negative zero frequencies omitted).

Now assuming the two finite zeros correspond to a frequency of ω₁ and ω₂, respectively. The frequency difference of ω₁ and ω₂ may be adjusted by directly varying capacitance of the grounding capacitor C. As an example, when the capacitance C=11.6 μF, the two zero frequencies ω₁ and ω₂ are 1.85 GHz and 4.3 GHz, respectively. As the capacitance C increases, the two zero frequencies ω₁ and ω₂ becomes more distant from each other, i.e. the higher one becomes further higher while the lower much lower. Since the characteristic that the frequency difference of the two zeros may be adjusted by directly varying capacitance of the grounding capacitor C, noise filtering over a specific case conducted by the inventive filter may be easily designed.

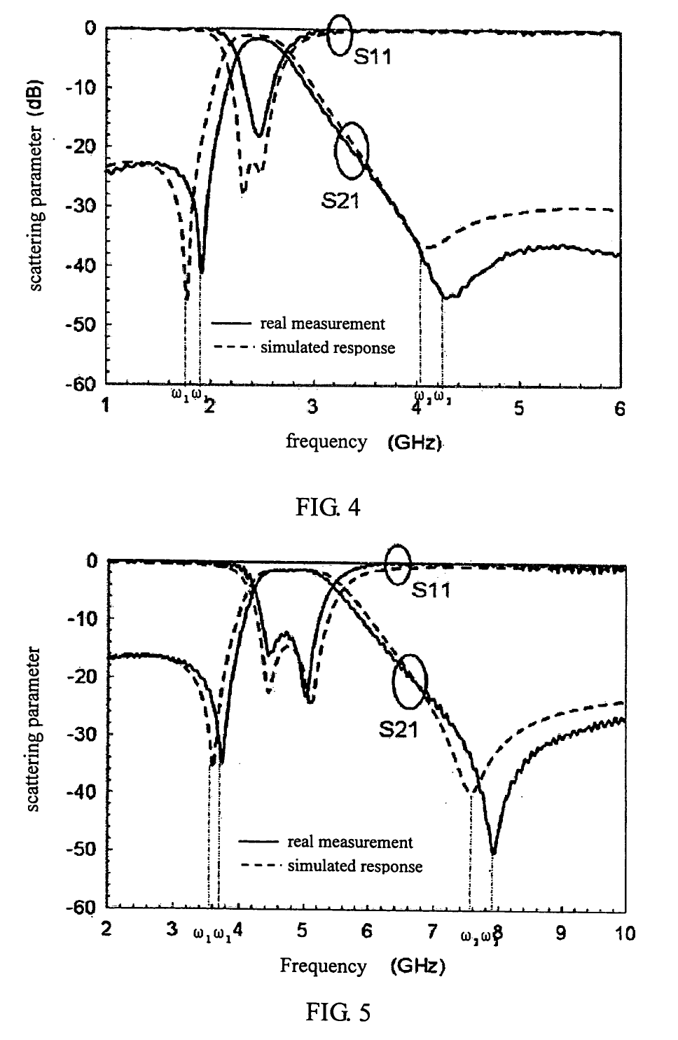

Referring to FIG. 4, a diagram showing frequency response of the second-order bandpass filter according to the present invention is depicted therein, in which a real measurement and a simulated response are both provided. As shown, the parameter S₂₁ is represented as a curve (although two curves are shown in the drawing) in a coordinate measured by frequency and scattering parameter, which is generally known as a frequency response curve. With a proper design of the capacitances of the used capacitors and inductances of the used inductors, the zeros may be located at 1.8-1.9 GHz (ω₁) and 4-4.4 GHz (ω₂), respectively. A pass band is located within a frequency range of 2.4 to 2.5 GHz while a stop band is located outside the range. In the filter, a signal processed is transmitted while a signal outside the range is stopped and filtered out. In a preferred embodiment, the zero ω₂ is adjusted to have a larger range 3.6-4.8 GHz. In addition, the frequency response presents a frequency width approximately as 100 MHz and a central frequency of pass band approximately as 2.45 GHz. Further, since signals corresponding to frequencies adjacent to the zero frequencies may be inhibited below −30 dB, noises may be efficiently filtered out. For the transmitted signal, loss of the pass band is approximately −1.6 dB, comparable to an average of those achieved in the two references. Since the insertion loss is low, the filter is suitable to be used for processing of communications signals. In addition, all the scattering parameters of the filter are negative, meaning that such filter is a passive device. A greater negative scattering parameter means a greater power loss filter, and vice versa.

To adapt the second-order bandpass filter to be properly used in the wireless LAN application, the capacitances and inductances have to be devised in compliance with IEEE 802.11b/g specification, i.e. frequencies of the interference signals (1.8 GHz, 1.9 GHz and 4.8 GHz) have to be presented at the zero frequencies or outside the pass band, so do GSM signals (with frequencies of 0.9 GHz, 1.8 GHz and 1.9 GHz) generally used in the wireless communications. The frequency response curve shown in FIG. 4 may satisfy these requirements by the following parameter settings: C₁=C₃=1.1 μF, C₂=C₄=2.52 μF, L₁=L₂=1.76 nH and C=11.6 μF. In the settings, the first and second capacitances have to be equal and the first and second inductances have also to be equal so that the rated central frequency may be achieved. However, these settings are not given in a limiting sense, but should be otherwise determined based upon the real applications. If these parameters of the components in the filter are not properly set, the frequency dependent parameters, central frequency, frequency width and zeros may not satisfy the requirements of the application. Such a frequency response case may be seen in FIG. 5. In the case shown in FIG. 5, the central frequency is approximately 4.8 GHz and the frequency width is approximately up to 800 MHz. Unfortunately, the two finite zeros fall at 3.7-3.8 GHz and 7.5-8 GHz, respectively, making the filter not efficient in inhibition of the aforementioned interference signals (frequency thereof is 4.8 GHz) and thus not suitable to be used in this application. Therefore, although the greater frequency width is provided at the cost of the reduced infinite zero number, the infinite zero may not filter out noises presented at some frequency band. As a result, the component parameters should be properly given in a manner such as that specified in FIG. 4.

Furthermore, the second-order bandpass filter of the invention also has the advantage that no extremely low capacitance or inductance is to be used therein. This feature may avoid the issue of frequency response shift since a greater manufacturing variation of the capacitors and inductors may be allowed. In addition, the second-order bandpass filter has a relatively smaller volume of 2.5×2.0×0.82 mm³ when fabricated by low temperature co-fired ceramic (LTCC) technology, compared with 4.3×2.0×0.55 mm³ and 3.8×0.4×0.5 mm³ achieved in the two references by the same technology, respectively.

Instead of the LTCC, the second-order bandpass filter may otherwise be fabricated as a form of the conventional discrete components and printing-based components or by other conventional technologies. However, LTCC is still the preferred choice since a smaller overall volume of the filter may be achieved thereby. As such, the purposes of compactness and slightness and susceptible of integration with other communications devices may be achieved.

In conclusion, the second-order bandpass filter of this invention has two finite zeros by providing a grounding capacitor therein. Further, a frequency width defined by the two finite zeros may be adjusted by directly varying capacitance of the grounding capacitor. Therefore, such second-order bandpass filter is reasonably suitable to be used in wireless LAN application.

While this invention has thus far been described in connection with the preferred embodiments thereof, it will readily be possible for those skilled in the art to put this invention into practice in various other manners or forms deduced from the preferred embodiment of the present invention. In this regard, scope of this invention should be defined in a broadened sense as drafted in the appended claims.

What is claimed is:

1. A second-order bandpass filter used to filter an input signal into an output signal, comprising:
a two-port network, comprising:
a first port, including:
a first blocking capacitor coupled electrically to an input signal at one end to filter out a direct current (DC) component of said input signal,
a first resonance capacitor coupled electrically to said other of said first blocking capacitor at one end; and
a first resonance inductor coupled electrically to said other of said first blocking capacitor at one end; and
a second port, including:
a second blocking capacitor coupled electrically to an output signal at one end to filter out a DC component of a signal at said second port;
a second resonance capacitor coupled electrically to said other of said second blocking capacitor at one end; and
a second resonance inductor coupled electrically to said other of said second blocking capacitor at one end and coupled electrically to ground at said other; and
a grounding capacitor, wherein a mutual induction is presented between said first and second resonance inductors.

2. The second-order bandpass filter according to claim 1, wherein said frequency response has two transmission zeros located at 1.8-1.9 GHz and 3.6-4.8 GHz, respectively.

3. The second-order bandpass filter according to claim 2, wherein said frequency response has a central frequency of about 2.45 GHz and a frequency width of greater than 100 MHz.

4. The second-order bandpass filter according to claim 1, wherein each of said first and second blocking capacitors has a capacitance of 1.1 μF, each of said first and second inductor has an inductance of 1.76 nH and said grounding capacitor has a capacitance of 11.6 μF.

5. The second-order bandpass filter according to claim 1, wherein said second-order bandpass filter is manufactured by low temperature co-fired ceramic technology.

6. The second-order bandpass filter according to claim 1, wherein said grounding capacitor provides two transmission zeros and a frequency bandwidth defined thereby is adjustable by directly varying capacitance of said grounding capacitor.
